(19) United States
(12) Patent Application Publication
(10) Pub. No.: US 2014/0217513 A1
(43) Pub. Date: Aug. 7, 2014

(54) SEMICONDUCTOR INTEGRATED CIRCUIT DEVICE

(71) Applicant: PANASONIC CORPORATION, Osaka (JP)

(72) Inventors: Kohtaro HAYASHI, Kyoto (JP); Hidetoshi NISHIMURA, Osaka (JP)

(73) Assignee: PANASONIC CORPORATION, Osaka (JP)

(21) Appl. No.: 14/248,213

(22) Filed: Apr. 8, 2014

Related U.S. Application Data
(63) Continuation of application No. PCT/JP2011/006090, filed on Oct. 31, 2011.

(51) Int. Cl. H01L 27/092

(52) U.S. Cl. CPC H01L 27/0928
USPC 257/369

(57) ABSTRACT

A first cell having a cell height N times as large as a reference cell height (N is an integer equal to or more than 2) is adjoined by a second cell in the cell width direction. A diffusion interconnect made of an impurity diffusion region is formed under a metal interconnect for power supply in the second cell. The first cell includes a transistor diffusion region formed, opposed to the diffusion interconnect, so as to stride across a region extended in the cell with direction of the metal interconnect. The diffusion interconnect is placed apart from the cell boundary in the cell width direction.

### CROSS-REFERENCE TO RELATED APPLICATIONS

This is a continuation of International Application No. PCT/JP2011/006090 filed on Oct. 31, 2011, the entire disclosure of which is incorporated by reference herein.

### BACKGROUND

The present disclosure relates to a semiconductor integrated circuit device having standard cells (hereinafter simply referred to as cells as appropriate), and more particularly to a layout where a so-called multi-height cell is adjoined by another cell.

A design method using standard cells is known as a method for designing a semiconductor integrated circuit. FIG. 20 is a layout example of a standard cell, where the dashed-dotted line defines the cell frame. The length of the standard cell in the Y direction (y1 in FIG. 20) is referred to as the cell height, and the length thereof in the X direction (x1 in FIG. 20) as the cell width. A cell having the same cell height as a reference height is referred to as a single-height cell. The cell width varies with the circuit configuration, or with the drive capability when the circuit configuration is same.

In FIG. 20, a power supply interconnect 501 and a ground interconnect 506 formed in a metal interconnect layer are placed to extend from the right end to the left end of the cell frame along the top and bottom ends, respectively, of the cell. PMOS transistors MP51 to MP53 are formed in an N-well NW, and NMOS transistors MN51 to MN53 are formed in a P-well PW. A P+ diffusion interconnect 502 made of a P-type impurity diffusion region is placed to underlie the power supply interconnect 501 and connected to the power supply interconnect 501 via contacts 503. An N+ diffusion interconnect 507 made of an N-type impurity diffusion region is placed to underlie the ground interconnect 506 and connected to the ground interconnect 506 via contacts 508.

In FIG. 20, also, P+ diffusion interconnects 504 and 505 branching from the P+ diffusion interconnect 502 are connected to source diffusion regions of the PMOS transistors MP51 to MP53, and N+ diffusion interconnects 509 and 510 branching from the N+ diffusion interconnect 507 are connected to source diffusion regions of the NMOS transistors MN51 to MN53. By contrast, FIG. 21 shows a layout configuration where diffusion interconnects 502A and 507A respectively placed under the power supply interconnect 501 and the ground interconnect 506 are used to fix the potentials of the wells NW and PW. The layouts in FIGS. 20 and 21 are well known as general layout configurations.

In general, the area of a semiconductor integrated circuit can be reduced by reducing the cell height of standard cells. However, when a cell including a complicate circuit such as a flipflop circuit or a cell large in drive capability is prepared to have the reference cell height, the cell width of such a cell becomes very large, resulting in increasing the area instead of decreasing it, in some cases.

For the above reason, there is known a technique of preparing such a cell as a multi-height cell having a cell height N times as large as the reference height (N is an integer equal to or more than 2). For example, a double-height cell having a cell height twice as large as the reference height has such a configuration that one of two single-height cells is inverted and such two single-height cells are integrated. A well having a height approximately twice as large as that of a well of a single-height cell is placed in the center portion of the cell in the cell height direction. Since transistors having a large gate width can be placed in such a well, a cell large in drive capability, for example, can be achieved.

Japanese Unexamined Patent Publication No. H07-249747 and No. 2001-237328 describe semiconductor integrated circuit devices.

### SUMMARY

In recent semiconductor integrated circuit devices, a multi-height cell described above is often placed in addition to a single-height cell, and thus standard cells having different cell heights are present in a mixed manner. On the other hand, each standard cell used for design must have a layout configuration that obeys the design rules even when the standard cell is adjoined by any other standard cell on its top, bottom, right, or left side.

FIG. 22 shows an example layout configuration where a single-height cell is placed to adjoin a double-height cell. CLa denotes the double-height cell, which has a P-well PW, an N-well NW and a P-well PW placed in this order from top in the cell height direction, and the height of the N-well NW in the center portion is twice as large as that of an N-well NW of the single-height cell. CLb denotes the single-height cell, which is placed so that the bottom end thereof is aligned with that of the cell CLa. That is, a ground interconnect 606 and an N+ diffusion interconnect 607 of the cell CLa are respectively connected to a ground interconnect 506 and an N+ diffusion interconnect 507 of the cell CLb. Also, the layout is designed in advance so that the spacing between the diffusion region of a transistor MP63a of the cell CLa and the diffusion region of a transistor MP51 of the cell CLb is equal to the minimum value SP under the separation rules. In other words, the diffusion regions of the transistors MP63a and MP51 are placed apart from the cell frame by ½ SP.

In the N-well NW of the double-height cell CLa, since no diffusion interconnect is placed under a power supply interconnect 611, a large diffusion region is secured for transistors. In the layout in FIG. 22, a large transistor MP62 large in gate width and thus in drive capability is formed.

In the single-height cell CLb, a P+ diffusion interconnect 502 extends to both ends of the cell frame along the top end. For this reason, in the double-height cell CLa, in order to obey the separation rules related to the P+ diffusion interconnect 502, a diffusion region formed in the N-well NW must be placed apart from the left end of the P+ diffusion interconnect 502 by the distance SP or more. Therefore, as for a gate interconnect GA63, the diffusion region must be divided into two in the cell height direction, and thus, failing to form a single transistor having a large gate width, two transistors MP63a and MP63b are formed. As for a gate interconnect GA61, also, the diffusion region is divided into two in the cell height direction, forming two transistors MP61a and MP61b.

Note that the entire diffusion region in the N-well NW of the double-height cell CLa has a recess shape further deeper than by the distance SP from the P+ diffusion interconnect 502 in FIG. 22. The reason for this is that there is also a limitation under the design rules related to the minimum size of the diffusion region relative to the gate electrode of a transistor.

As described above, in the wide well in the center portion of the double-height cell, the transistors placed near both ends in the cell width direction are not allowed to secure a sufficiently large gate width under the design rules in consideration of the layout configuration of an adjoining cell. Therefore, improvement in the drive capability of transistors, which is one of the objectives for using a double-height cell, cannot be necessarily sufficiently achieved. In particular, in order for a PMOS transistor, which is low in current capability, to secure large drive capability with a small area, it is desirable to form a transistor having a large gate width by making full use of the region available for formation of PMOS transistors.

In addition, in a microfabrication process, in order to prevent or reduce variations in the shape of gate electrodes of transistors, a dummy gate is sometimes placed on a cell boundary to ensure placement of gate electrodes at an equal pitch. For example, in FIG. 22, it is necessary to place a dummy gate on the cell boundary at the same pitch as the gates GA61 to GA63. However, if a dummy gate is placed on the cell boundary in the layout in FIG. 22, an unnecessary transistor will be formed by the P+ diffusion interconnect 502 and the dummy gate.

The problem described above is not limited to the double-height cell, but can arise in a multi-height cell having a layout configuration where a wide well is formed and a diffusion interconnect of another cell can adjoin the well.

It is an objective of the present disclosure to provide a layout configuration of a semiconductor integrated circuit device where a multi-height cell is adjoined by another cell, where improvement in the drive capability of transistors in the multi-height cell can be sufficiently achieved.

According to an aspect of the present disclosure, a semiconductor integrated circuit device where a plurality of cells are placed is provided, the plurality of cells including: a first cell that is a multi-height cell having a cell height N times as large as a reference cell height (N is an integer equal to or more than 2); and a second cell placed to adjoin the first cell in a cell width direction, wherein the second cell includes a first metal interconnect placed to extend in the cell width direction along one end in a cell height direction, and a first diffusion interconnect that is made of an impurity diffusion region formed to extend under the first metal interconnect in the cell width direction and connected to the first metal interconnect via contacts, the first cell includes a first transistor diffusion region that is opposed to the first diffusion interconnect in the cell width direction, is formed to stride across, in the cell height direction, a region extended in the cell width direction of the first metal interconnect, and constitutes a transistor, and the first diffusion interconnect is placed apart from a cell boundary between the first cell and the second cell in the cell width direction.

According to the aspect described above, the second cell placed to adjoin the first cell that is a multi-height cell includes a first metal interconnect extending in the cell width direction along one end in the cell height direction and a first diffusion interconnect made of an impurity diffusion region formed to extend under the metal interconnect in the cell width direction. The first cell includes a first transistor diffusion region formed to stride across, in the cell height direction, a region extended in the cell width direction of the first metal interconnect of the second cell. The first diffusion interconnect of the second cell opposed to the first transistor diffusion region is apart from the cell boundary between the first cell and the second cell in the cell width direction. This ensures obedience of the separation rules related to the spacing between the first transistor diffusion region of the first cell and the diffusion interconnect of the second cell, eliminating the necessity of dividing the first transistor diffusion region into parts. Therefore, a transistor large in gate width can be formed even near another cell placed adjacently without being affected by the layout of the cell.

According to the present disclosure, in a multi-height cell, a transistor large in gate width can be formed even near another cell placed adjacently. Thus, the drive capability of a transistor in a multi-height cell can be improved compared with that conventionally achieved.

### BRIEF DESCRIPTION OF THE DRAWINGS

FIG. 1 is a plan view showing a layout configuration of a single-height cell in the first embodiment.

FIG. 2 is a plan view showing a layout configuration of a double-height cell in the first embodiment.

FIG. 3 is a plan view showing a layout configuration of a semiconductor integrated circuit device of the first embodiment.

FIG. 4 is a plan view showing a layout configuration of a single-height cell in the second embodiment.

FIG. 5 is a plan view showing a layout configuration of a double-height cell in the second embodiment.

FIG. 6 is a plan view showing a layout configuration of a semiconductor integrated circuit device of the second embodiment.

FIG. 7 is a plan view showing a layout configuration of the semiconductor integrated circuit device of the second embodiment.

FIG. 8 is a plan view showing another example of the layout configuration of the semiconductor integrated circuit device of the second embodiment.

FIG. 9 is a view showing part of a design flow of a semiconductor integrated circuit device of the third embodiment.

FIG. 10 is a view showing design data of a single-height cell in the third embodiment.

FIG. 11 is a view showing design data of a double-height cell in the third embodiment.

FIG. 12 shows an example of layout design data created in a layout design step S11 in FIG. 9.

FIG. 13 is a plan view showing a layout configuration of the semiconductor integrated circuit device of the third embodiment.

FIG. 14 shows an example of layout design data created in the layout design step S11 in FIG. 9.

FIG. 15 is a plan view showing a layout configuration of the semiconductor integrated circuit device of the third embodiment.

FIG. 16 is a view showing design data of a single-height cell in the fourth embodiment.

FIG. 17 is a view showing design data of a double-height cell in the fourth embodiment.

FIG. 18 is a plan view showing a layout configuration of a semiconductor integrated circuit device of the fourth embodiment.

FIG. 19 is a plan view showing another example of the layout configuration of a single-height cell in an embodiment.

FIG. 20 is a plan view showing a layout configuration of a general single-height cell.

FIG. 21 is a plan view showing a layout configuration of another general single-height cell.

FIG. 22 is a view for explaining a problem to be solved by the present disclosure.

### DETAILED DESCRIPTION

Embodiments of the present disclosure will be described hereinafter with reference to the accompanying drawings.

### First Embodiment

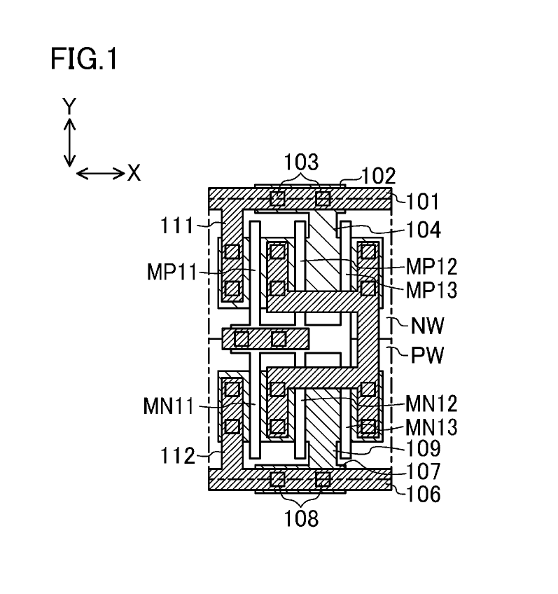

FIG. 1 is a plan view showing a layout configuration of a single-height cell in the first embodiment. The single-height cell is a cell having the reference cell height. In FIG. 1, the dashed-dotted line defines the cell frame. The lateral direction (X direction) in FIG. 1 is the cell width direction, and the longitudinal direction (Y direction) is the cell height direction (this also applies to the other figures).

In FIG. 1, MP11 to MP13 denote PMOS transistors formed in an N-well NW, and MN11 to MN13 denote NMOS transistors formed in a P-well PW. A power supply interconnect 101 and a ground interconnect 106 are both formed in a first metal interconnect layer, and placed to extend from the right end to the left end of the cell frame in the cell width direction along the top and bottom ends, respectively, of the single-height cell in the cell height direction. The center line of the power supply interconnect 101 corresponds with the top end of the cell frame, and the center line of the ground interconnect 106 corresponds with the bottom end of the cell frame. A P+ diffusion interconnect 102 is made of a P-type impurity diffusion region formed to extend under the power supply interconnect 101 in the cell width direction, and connected to the power supply interconnect 101 via contacts 103. An N+ diffusion interconnect 107 is made of an N-type impurity diffusion region placed to extend under the ground interconnect 106 in the cell width direction, and connected to the ground interconnect 106 via contacts 108.

In the configuration in FIG. 1, the P+ diffusion interconnect 102 and the N+ diffusion interconnect 107 are placed apart from the left and right ends of the cell frame in the cell width direction by a predetermined spacing. In the illustrated example, the spacing corresponds to the sum of the width of one contact and the spacing between adjacent contacts (i.e., corresponds to one grid spacing in the contact arrangement). Therefore, an interconnect 111 branching from the power supply interconnect 101 is connected to the source diffusion region of the PMOS transistor MP11 via contacts, and an interconnect 112 branching from the ground interconnect 106 is connected to the source diffusion region of the NMOS transistor MN11 via contacts. Although the interconnects 111 and 112 are formed in the first metal interconnect layer, the influence of such interconnects on the use of the first metal interconnect layer as the interconnect region is restrictive because they are placed in restricted regions located upper left and lower left in the cell. Note that a P+ diffusion interconnect 104 branching from the P+ diffusion interconnect 102 is connected to the source diffusion regions of the PMOS transistors MP12 and MP13, and an N+ diffusion interconnect 109 branching from the N+ diffusion interconnect 107 is connected to the source diffusion regions of the NMOS transistors MN12 and MN13.

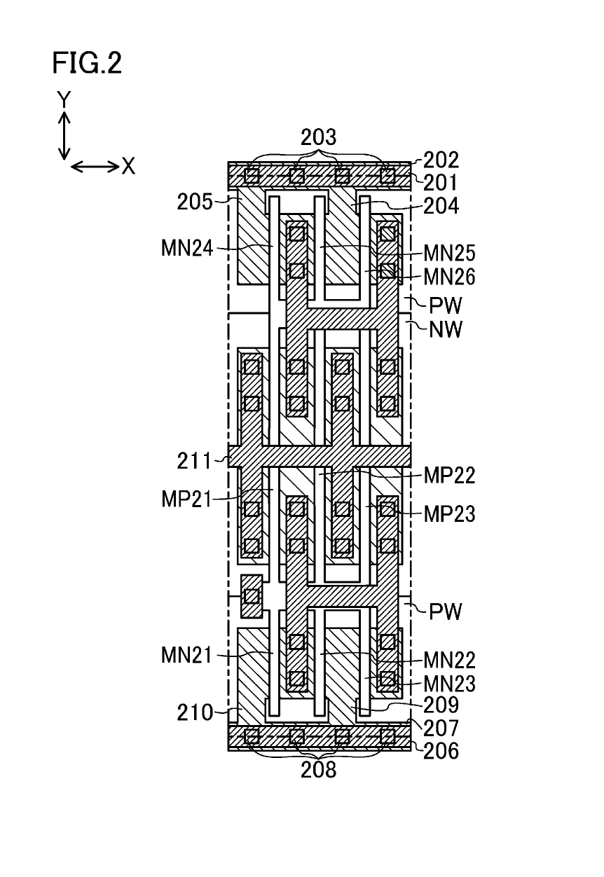

FIG. 2 is a plan view showing a layout configuration of a double-height cell in this embodiment. The double-height cell is a cell having a cell height twice as large as the reference cell height.

In FIG. 2, MP21 to MP23 denote PMOS transistors formed in an N-well NW, and MN21 to MN23 and MN24 to MN26 denote NMOS transistors formed in P-wells PW. In the configuration in FIG. 2, the PMOS transistors MP21 to MP23 placed in the N-well NW are not divided into parts in the cell height direction, and the outer shape of the entire diffusion region constituting the PMOS transistors MP21 to MP23 is rectangular having no recess. A power supply interconnect 211 is formed in the first metal interconnect layer, and placed to extend from the right end to the left end of the cell frame in the cell width direction in the center portion of the double-height cell in the cell height direction. Interconnects branching from the power supply interconnect 211 are connected to the source diffusion regions of the PMOS transistors MP21 to MP23 via contacts.

Ground interconnects 201 and 206 are formed in the first metal interconnect layer, and placed to extend from the right end to the left end of the cell frame in the cell width direction along both ends of the double-height cell in the cell height direction. The center lines of the ground interconnects 201 and 206 respectively correspond with the top and bottom ends of the cell frame. An N+ diffusion interconnect 202 is made of an N-type impurity diffusion region formed to extend under the ground interconnect 201 in the cell width direction, and connected to the ground interconnect 201 via contacts 203. An N+ diffusion interconnect 207 is made of an N-type impurity diffusion region formed to extend under the ground interconnect 206 in the cell width direction, and connected to the ground interconnect 206 via contacts 208. N+ diffusion interconnects 204 and 205 branching from the N+ diffusion interconnect 202 are connected to the source diffusion regions of the transistors MN24 to MN26, and N+ diffusion interconnects 209 and 210 branching from the N+ diffusion interconnect 207 are connected to the source diffusion regions of the transistors MN21 to MN23.

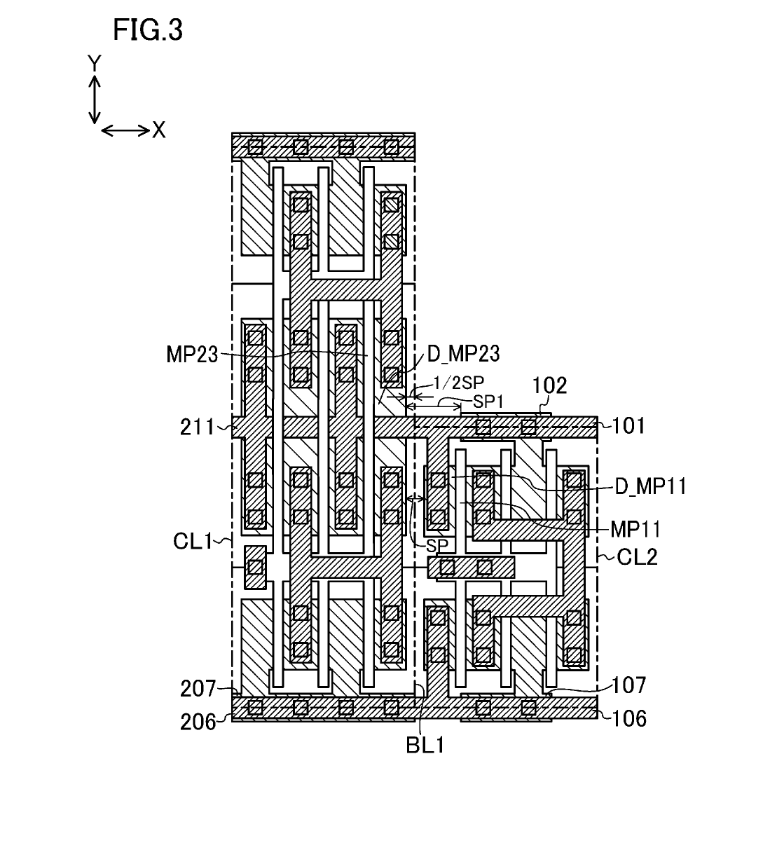

FIG. 3 is a plan view showing a layout configuration of a semiconductor integrated circuit device of this embodiment, where a first cell CL1 having the same configuration as the double-height cell shown in FIG. 2 and a second cell CL2 having the same configuration as the single-height cell shown in FIG. 1 are placed to adjoin each other in the cell width direction.

In the configuration in FIG. 3, the first and second cells CL1 and CL2 are placed so that the bottom ends thereof are aligned with each other, where the ground interconnect 206 as the third metal interconnect of the first cell CL1 and the ground interconnect 106 as the second metal interconnect of the second cell CL2 are placed to be in line with each other in the cell width direction and connected to each other. However, the N+ diffusion interconnect 207 formed along the bottom end of the first cell CL1 and the N+ diffusion interconnect 107 formed along the bottom end of the second cell CL2 are not connected to each other because the N+ diffusion interconnect 107 as the second diffusion interconnect is placed apart from the cell frame by a predetermined spacing (corresponding to one grid spacing in the illustrated example).

Also, in the center portion of the first cell CL1 in the cell height direction, the power supply interconnect 211 is connected to the power supply interconnect 101 as the first metal interconnect of the second cell CL2. In the first cell CL1, a drain diffusion region D_MP23 of the transistor MP23 is formed, opposed to the P+ diffusion interconnect 102 of the second cell CL2 in the cell width direction, so as to stride across, in the cell height direction, a region extended in the cell width direction of the power supply interconnect 101 of the second cell CL2. However, since the P+ diffusion interconnect 102 as the first diffusion interconnect is placed apart from the cell frame by a predetermined spacing (corresponding to one grid spacing in the illustrated example), the spacing between the drain diffusion region D_MP23 as the first transistor diffusion region and the P+ diffusion interconnect 102 is SP1 that is larger than the minimum value SP under the separation rules related to the spacing between diffusion regions. Note that the drain diffusion region D_MP23 of the transistor MP23 is placed apart from the cell frame by a spacing of ½ SP. The spacing SP1 between the drain diffusion region D_MP23 and the P+ diffusion interconnect 102 is larger than the minimum spacing SP between the drain diffusion region D_MP23 and an opposed source diffusion region D_MP11 as the first diffusion region of the transistor MP11. Also, the drain diffusion region D_MP23 of the transistor MP23 is in a rectangular shape having no recess.

In other words, since the P+ diffusion interconnect 102 is placed apart from a cell boundary BL1 between the first cell CL1 and the second cell CL2 in the cell width direction, it is unnecessary to divide the PMOS transistor MP23 of the first cell CL1 into upper and lower parts under the separation rules for the spacing from the P+ diffusion interconnect 102. Accordingly, in the N-well NW, a PMOS transistor large in gate width can be formed even near both ends of the cell in the cell width direction, and thus the drive capability can be improved compared with the conventional double-height cell.

Also, both the diffusion interconnects 102 and 107 placed along the top and bottom ends of the second cell CL2 are apart from the cell frame at both ends. Therefore, no design rule error will occur even if the second cell CL2 is placed in a horizontally inverted position or in a vertically inverted position.

In this embodiment, where the diffusion interconnects placed at both ends of the single-height cell in the cell height direction are placed apart from the cell frame in the cell width direction by a predetermined spacing, the gate width of the transistors placed in the well in the center portion of the double-height cell can be increased. This can improve the drive capability of the cell. Also, since the layout configuration described in this embodiment can be easily achieved by modifying the conventional layout, only a small number of steps are necessary to accommodate this.

### Second Embodiment

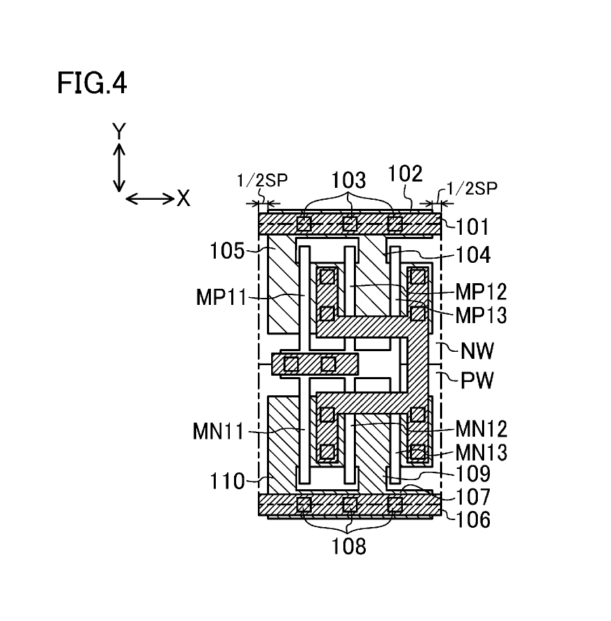

FIG. 4 is a plan view showing a layout configuration of a single-height cell in the second embodiment. In FIG. 4, common components shared with FIG. 1 are denoted by the same reference characters, and detailed description of such components is omitted here.

The layout configuration in FIG. 4 is roughly similar to that in FIG. 1, where the P+ diffusion interconnect 102 and the N+ diffusion interconnect 107 are placed apart from the right and left ends of the cell frame in the cell width direction by a predetermined spacing. The predetermined spacing is however different from that in FIG. 1. In FIG. 4, the P+ diffusion interconnect 102 and the N+ diffusion interconnect 107 are placed apart from the right and left ends of the cell frame by ½ SP. Also, the placement positions of the contacts 103 for connecting the P+ diffusion interconnect 102 and the power supply interconnect 101 and the contacts 108 for connecting the N+ diffusion interconnect 107 and the ground interconnect 106 are displaced with respect to the contacts on the diffusion regions constituting the transistors by a half grid spacing each.

By the above configuration, the P+ diffusion interconnect 102 and the N+ diffusion interconnect 107 are larger in size than those in the first embodiment, permitting formation of diffusion interconnects satisfying the minimum area rules related to diffusion interconnects even in a cell small in cell width, for example. Also, by displacing the contacts for the diffusion interconnects by a half grid spacing, sufficient overlaps between the contacts and the diffusion interconnects can be secured, and also the number of contacts can be increased compared with that in the first embodiment.

Moreover, in the layout configuration in FIG. 4, a diffusion interconnect 105 branching from the P+ diffusion interconnect 102 is connected to the source diffusion region of the PMOS transistor MP11, and a diffusion interconnect 110 branching from the N+ diffusion interconnect 107 is connected to the source diffusion region of the NMOS transistor MN11. By this configuration, since a larger number of diffusion interconnects can be used for supply of the power supply potential or the ground potential to the source diffusion regions of the transistors than in the layout configuration in FIG. 1, the first metal interconnect layer can be used more effectively as the interconnect region.

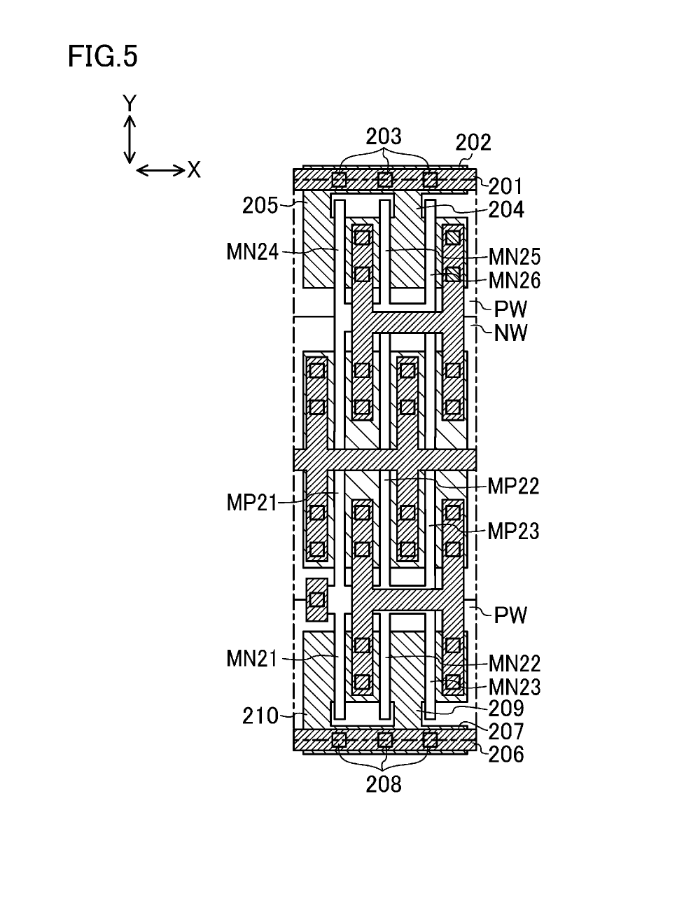

FIG. 5 is a plan view showing a layout configuration of a double-height cell in this embodiment. In FIG. 5, common components shared with FIG. 2 are denoted by the same reference characters, and detailed description of such components is omitted here.

The layout configuration in FIG. 5 is roughly similar to that in FIG. 2, but is different therefrom in that the N+ diffusion interconnects 202 and 207 are placed apart from the right and left ends of the cell frame in the cell width direction by a predetermined spacing. In FIG. 5, the N+ diffusion interconnects 202 and 207 are placed apart from the right and left ends of the cell frame by ½ SP. Also, the placement positions of the contacts 203 for connecting the N+ diffusion interconnect 202 and the ground interconnect 201 and the contacts 208 for connecting the N+ diffusion interconnect 207 and the ground interconnect 206 are displaced with respect to the contacts on the diffusion regions constituting the transistors by a half grid spacing each.

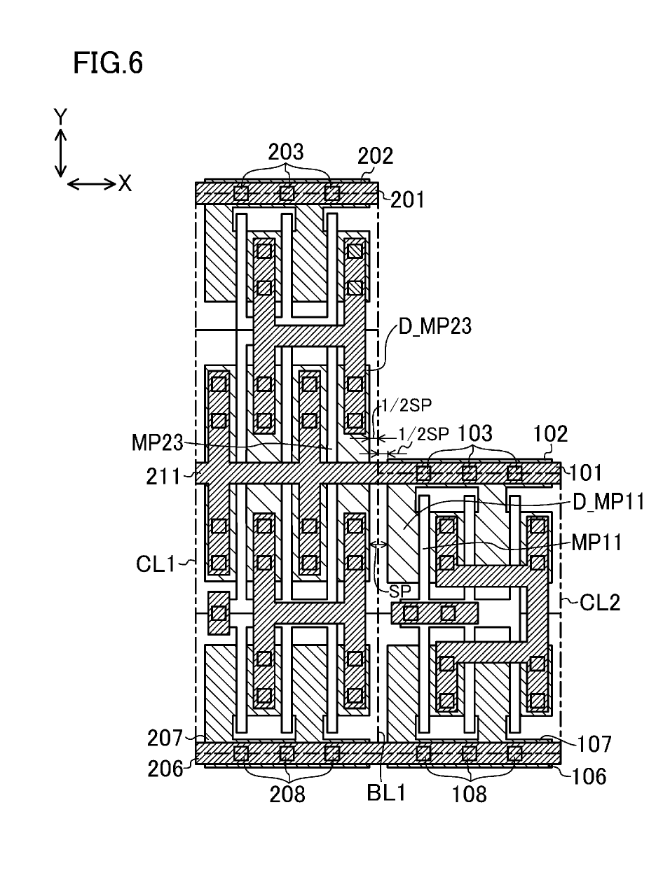

FIG. 6 is a plan view showing a layout configuration of a semiconductor integrated circuit device of this embodiment, where a first cell CL1 having the same configuration as the double-height cell shown in FIG. 5 and a second cell CL2 having the same configuration as the single-height cell shown in FIG. 4 are placed to adjoin each other in the cell width direction.

In the configuration in FIG. 6, the first and second cells CL1 and CL2 are placed so that the bottom ends thereof are aligned with each other, where the ground interconnect 206 of the first cell CL1 and the ground interconnect 106 of the second cell CL2 are placed to be in line with each other in the cell width direction and connected to each other. However, the N+ diffusion interconnect 207 formed along the bottom end of the first cell CL1 and the N+ diffusion interconnect 107 formed along the bottom end of the second cell CL2 are not connected to each other because both the N+ diffusion interconnects 107 and 207 are placed apart from the cell frame by a predetermined spacing (½ SP in the illustrated example).

Also, in the center portion of the first cell CL1 in the cell height direction, the power supply interconnect 211 is connected to the power supply interconnect 101 of the second cell CL2. In the first cell CL1, a drain diffusion region D_MP23 of the transistor MP23 is formed, opposed to the P+ diffusion interconnect 102 of the second cell CL2 in the cell width direction, so as to stride across, in the cell height direction, a region extended in the cell width direction of the power supply interconnect 101 of the second cell CL2. However, since the P+ diffusion interconnect 102 is placed apart from the cell frame by a predetermined spacing (½ SP in the illustrated example), the spacing between the drain diffusion region D_MP23 and the P+ diffusion interconnect 102 is the minimum value SP under the separation rules related to the spacing between diffusion regions. This is equal to the minimum spacing SP between the drain diffusion region D_MP23 and the opposed source diffusion region D_MP11 of the transistor MP11. Note that the drain diffusion region D_MP23 of the transistor MP23 is placed apart from the cell frame by a spacing of ½ SP, and is in a rectangular shape having no recess.

In other words, since the P+ diffusion interconnect 102 is placed apart from the cell boundary BL1 between the first cell CL1 and the second cell CL2 in the cell width direction, it is unnecessary to divide the PMOS transistor MP23 of the first cell CL1 into upper and lower parts under the separation rules related to the P+ diffusion interconnect 102. Accordingly, in the N-well NW, a PMOS transistor large in gate width can be formed even near both ends of the cell in the cell width direction, and thus the drive capability can be improved compared with the conventional double-height cell.

Moreover, the spacing between the contact, out of the contacts 208 in the first cell CL1, closest to the cell boundary BL1 and the cell boundary BL1 is equal to the spacing between the contact, out of the contacts 108 in the second cell CL2, closest to the cell boundary BL1 and the cell boundary BL1.

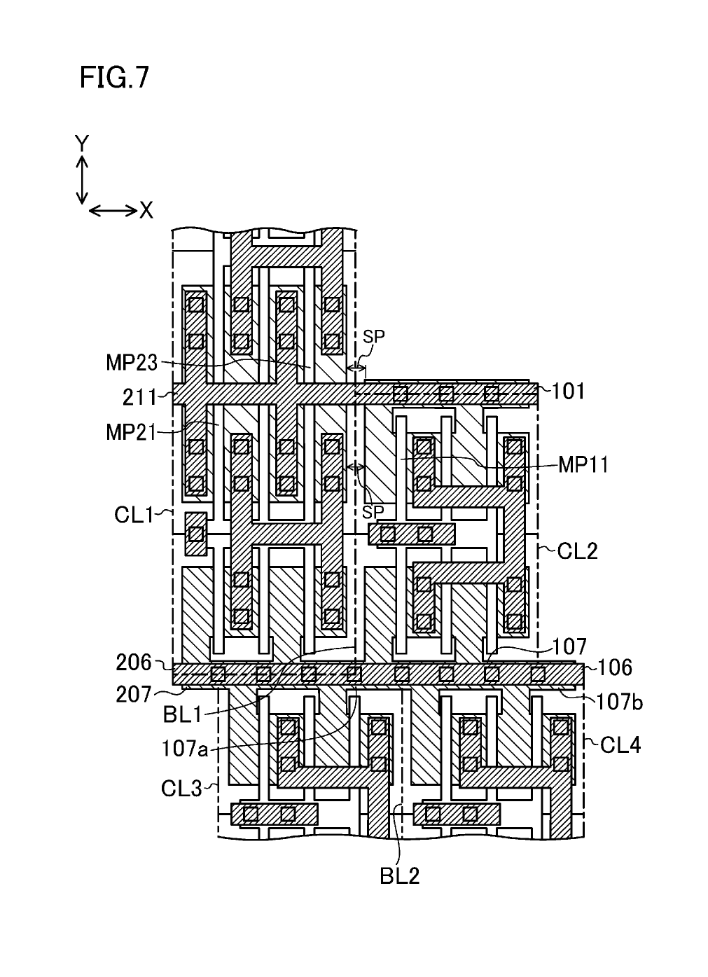

FIG. 7 shows a layout in which third and fourth cells CL3 and CL4 having the same configuration as the single-height cell shown in FIG. 4 are further placed to adjoin the configuration in FIG. 6. The third and fourth cells CL3 and CL4 are placed to adjoin each other in the cell width direction, and placed to adjoin the first and second cells CL1 and CL2 in the cell height direction so as to share the ground interconnects 206 and 106. Since the contacts on the diffusion interconnects along the top and bottom ends of the cell frame are on the same grid in the single-height cell in FIG. 4 and the double-height cell in FIG. 5, such cells can be placed to adjoin each other vertically.

Also, in the configuration in FIG. 7, the position of a cell boundary BL2 between the third and fourth cells CL3 and CL4 in the cell width direction is displaced from the cell boundary BL1 between the first and second cells CL1 and CL2 in the cell width direction. Therefore, the third cell CL3 is placed so as to stride across the cell boundary BL1 between the first and second CL1 and CL2, whereby the space between the N+ diffusion interconnects 207 and 107 is filled with an N+ diffusion interconnect 107a of the third cell CL3. Likewise, the space on the right of the N+ diffusion interconnect 107 is filled with an N+ diffusion interconnect 107b of the fourth cell CL4. That is, the diffusion interconnects 207, 107a, 107, and 107b formed under the ground interconnects 206 and 106 are placed across the cell boundary BL1 continuously without any clearance. By this placement, also, the number of contacts increases. Accordingly, the resistance value of the ground interconnects 206 and 106 can be further reduced. Note that the resistance value of the power supply interconnects can also be reduced in a similar manner.

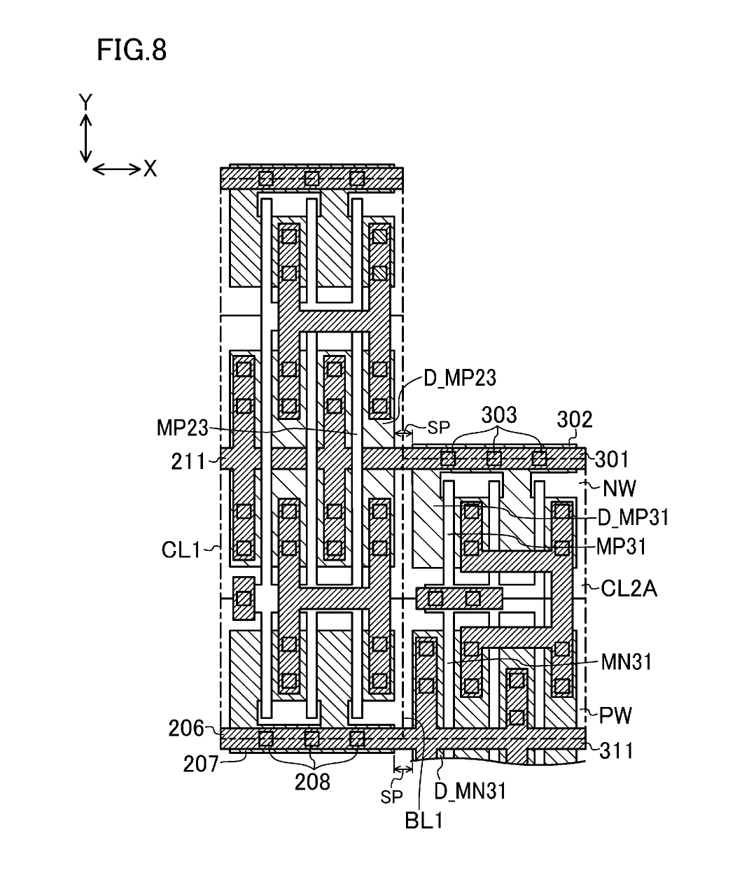

FIG. 8 is a plan view showing another example of the layout configuration of the semiconductor integrated circuit device of this embodiment, where the first cell CL1 having the same configuration as the double-height cell in FIG. 5 and a second cell CL2A that is a double-height cell having a different configuration are placed to adjoin each other in the cell width direction.

The second cell CL2A has a configuration where the N-well NW and the P-well PW of the double-height cell in FIG. 5 are interchanged with each other. More specifically, a power supply interconnect 301 as the first metal interconnect is placed to extend in the cell width direction along the top end of the cell in the cell height direction, and a P+ diffusion interconnect 302 as the first diffusion interconnect is formed under the power supply interconnect 301. The power supply interconnect 301 and the P+ diffusion interconnect 302 are connected via contacts 303. The P+ diffusion interconnect 302 is placed apart from the right and left ends of the cell frame in the cell width direction by ½ SP. The placement positions of the contacts 303 for connecting the P+ diffusion interconnect 302 and the power supply interconnect 301 are displaced with respect to the contacts on the diffusion regions constituting the transistors by a half grid spacing each.

In the configuration in FIG. 8, also, the spacing between the drain diffusion region D_MP23 and the P+ diffusion interconnect 302 is the minimum value SP under the separation rules related to the spacing between diffusion regions. In other words, the spacing SP between the drain diffusion region D_MP23 and the P+ diffusion interconnect 302 is equal to the minimum spacing between the drain diffusion region D_MP23 and a source diffusion region D_MP31 of a transistor MP31. That is, a similar advantage to that of the configuration in FIG. 6 can be obtained.

Also, in the center portion of the second cell CL2A in the cell height direction, a ground interconnect 311 is connected to the ground interconnect 206 as the third metal interconnect of the first cell CL1. In the second cell CL2A, a source diffusion region D_MN31 of a transistor MN31 is formed, opposed to the N+ diffusion region 207 as the third diffusion interconnect of the first cell CL1 in the cell width direction, so as to stride across, in the cell height direction, a region extended in the cell width direction of the ground interconnect 206 of the first cell CL1. However, since the N+ diffusion interconnect 207 is placed apart from the cell frame by ½ SP, the spacing between the drain diffusion region D_MN31 as the second transistor diffusion region and the N+ diffusion interconnect 207 is the minimum value SP under the separation rules related to the spacing between diffusion regions. It is therefore unnecessary to divide the NMOS transistor MN31 of the second cell CL2A into upper and lower parts under the separation rules related to the N+ diffusion interconnect 207. Accordingly, in the P-well PW, an NMOS transistor large in gate width can be formed even near both ends of the cell in the cell width direction.

Note that, while the configuration where a double-height cell adjoins the first cell CL1 has been described with reference to FIG. 8, a similar configuration can also be implemented with a multi-height cell having a cell height M times as large as the reference cell height (M is an integer equal to or more than 2) adjoining the first cell CL1. For example, the second cell CL2A in FIG. 8 may be a multi-height cell having a cell height three times as large as the reference cell height and having an N-well, a P-well, an N-well and a P-well in this order from top in the cell height direction.

### Third Embodiment

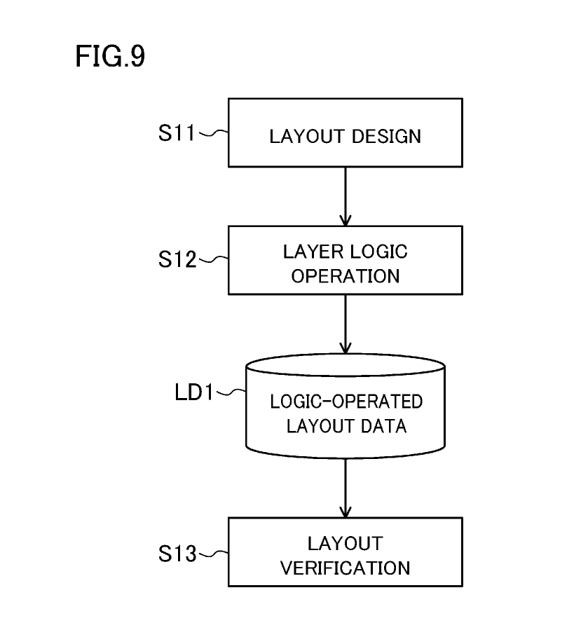

FIG. 9 is a view showing part of a design flow of a semiconductor integrated circuit device of the third embodiment. In FIG. 9, S11 denotes a layout design step, where placement of standard cells, wiring between standard cells, etc. are performed, to create layout design data. In this step, standard cells are placed using the cell frames as the basis. S12 denotes a layer logic operation step, where the layout design data created in the layout design step S11 is subjected to layout change considering overlapping of logic-operation-use layers. The logic-operation-use layers are special layers used on design data for layout correction or modification and do not appear in the actual layout configuration. S13 denotes a layout verification step, where the logic-operated layout data LD1 is checked for the design rules, etc.

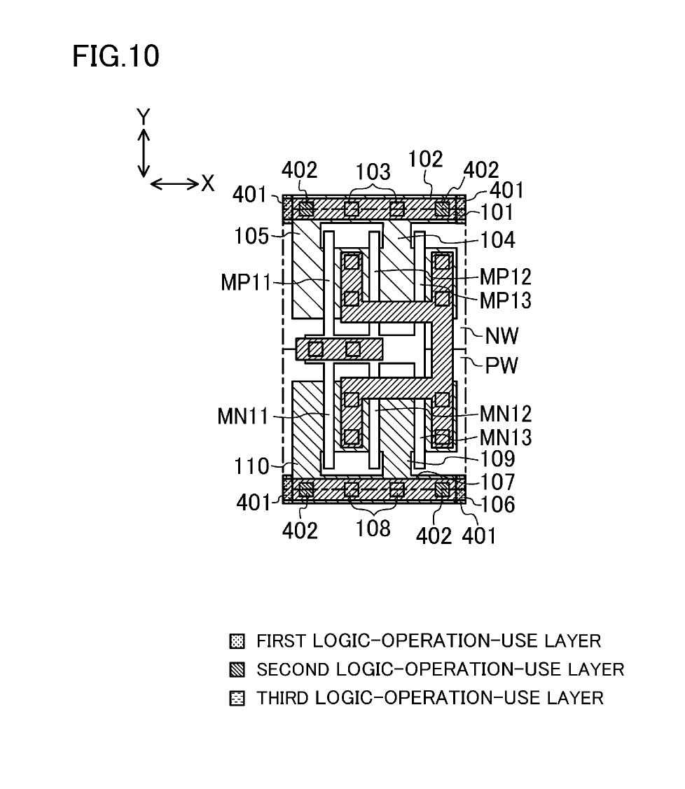

FIG. 10 is a view showing design data of a single-height cell in this embodiment. In FIG. 10, the P+ diffusion interconnect 102 and the N+ diffusion interconnect 107 extend up to both ends of the cell frame in the cell width direction, and first logic-operation-use layers 401 having the same width as the P+ diffusion interconnect 102 and the N+ diffusion interconnect 107 are placed in ranges of the interconnects 102 and 107 inward from both ends by a distance of ½ SP each. Also, the contacts 103 and 108 on the P+ diffusion interconnect 102 and the N+ diffusion interconnect 107 are placed on the same grid as the contacts placed on the diffusion regions constituting the transistors. Second logic-operation-use layers 402 having the same shape as the contacts are placed on only the contacts, out of the contacts 103 and 108, at both ends in the cell width direction. The configuration except for the above is similar to the single-height cell shown in FIG. 4.

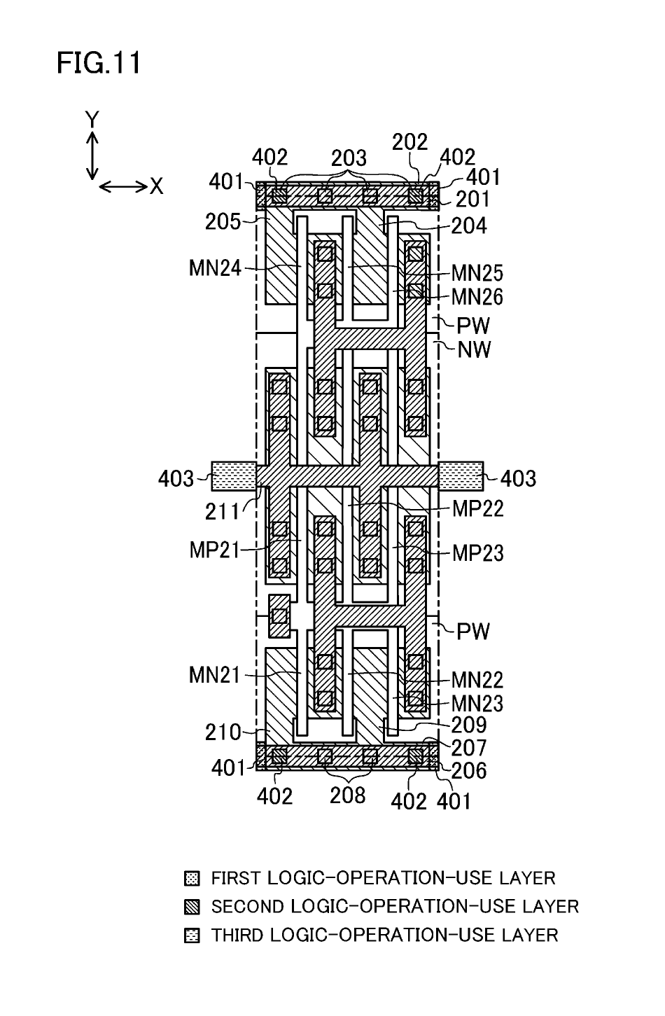

FIG. 11 is a view showing design data of a double-height cell in this embodiment. In FIG. 11, the N+ diffusion interconnects 202 and 207 extend up to both ends of the cell frame in the cell width direction, and first logic-operation-use layers 401 having the same width as the N+ diffusion interconnects 202 and 207 are placed in ranges of the interconnects 202 and 207 inward from both ends by a distance of ½ SP each. Also, the contacts 203 and 208 on the N+ diffusion interconnects 202 and 207 are placed on the same grid as the contacts placed on the diffusion regions constituting the transistors. Second logic-operation-use layers 402 having the same shape as the contacts are placed on only the contacts, out of the contacts 203 and 208, at both ends in the cell width direction. Moreover, third logic-operation-use layers 403 are placed to extend outward from the cell frame in the center portion of the double-height cell in the cell height direction. The third logic-operation-use layers 403 have the same width as the P+ diffusion interconnect of the single-height cell and a length of at least ½ SP or more. The configuration except for the above is similar to the double-height cell shown in FIG. 5.

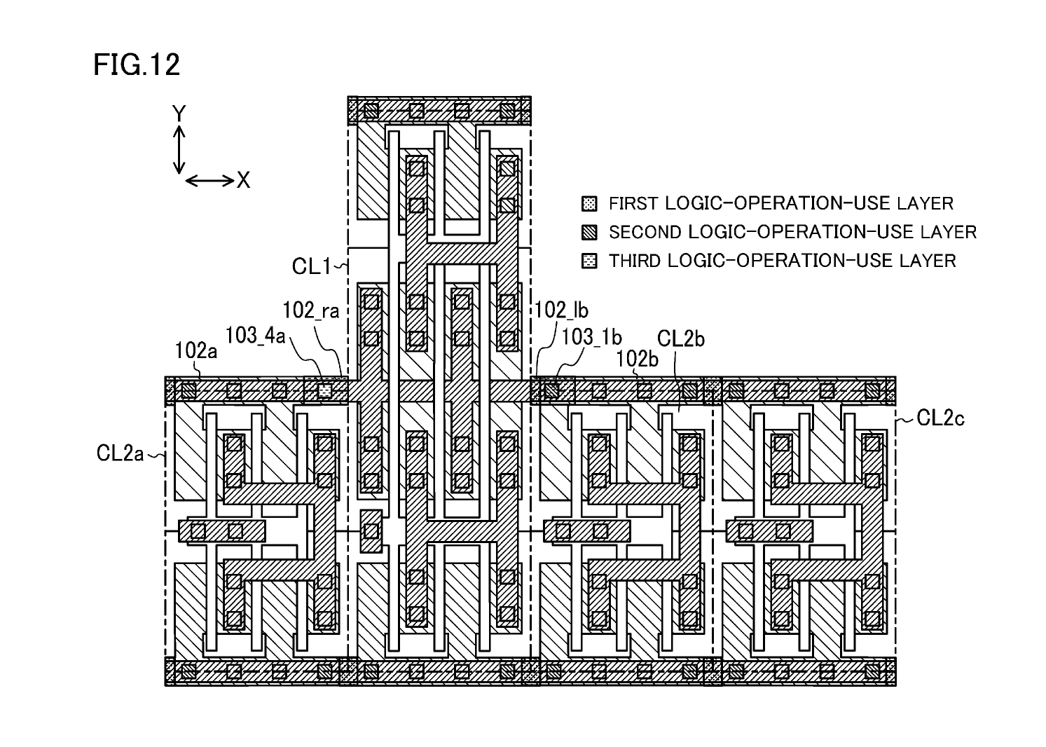

FIG. 12 shows an example of layout design data created in the layout design step S11, where single-height cells CL2a, CL2b, and CL2c having the configuration shown in FIG. 10 are placed on both sides of a double-height cell CL1 having the configuration shown in FIG. 11. The cells CL1, CL2a, CL2b, and CL2c are placed so that the bottom ends of their cell frames are aligned with one another in the cell height direction.

In the layer logic operation step S12, for the layout design data created in the layout design step S11, portions of the P+ diffusion interconnects and the N+ diffusion interconnects where the first logic-operation-use layers 401 and the third logic-operation-use layers 403 overlap are deleted. Also, contacts in portions where the second logic-operation-use layers 402 and the third logic-operation-use layers 403 overlap are deleted. In the layout design data in FIG. 12, in the cell CL2a, a range 102_ra of a P+ diffusion interconnect 102a inward from the right end of the cell by a distance of ½ SP and a contact 103_4a, out of the contacts on the P+ diffusion interconnect 102a, closest to the right end of the cell are deleted. Likewise, in the cell CL2b, a range 102_1b of a P+ diffusion interconnect 102b inward from the left end of the cell by a distance of ½ SP and a contact 103_1b, out of the contacts on the P+ diffusion interconnect 102b, closest to the left end of the cell are deleted.

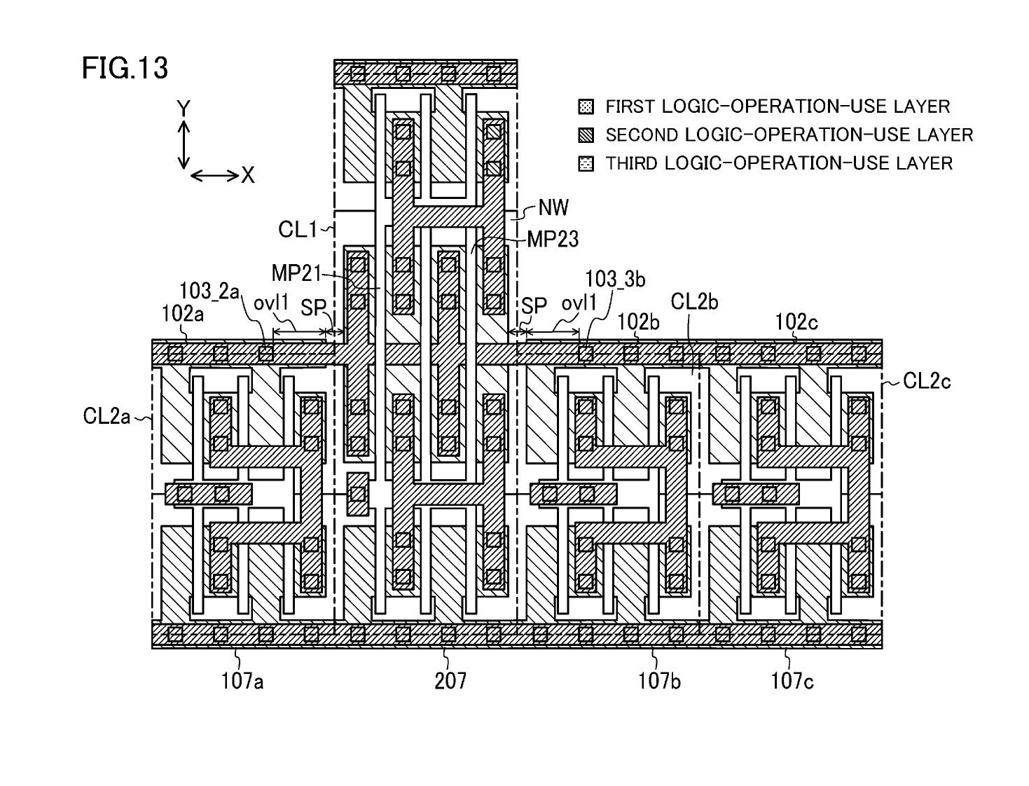

FIG. 13 shows layout design data after execution of the layer logic operation step S12, which corresponds to a layout plan view of the semiconductor integrated circuit device of this embodiment. Note that interconnects between the standard cells placed in the layout design step S11 are omitted in FIG. 13. In FIG. 13, the spacing between the diffusion region of the transistor MP21 of the cell CL1 and the P+ diffusion interconnect 102a of the cell CL2a, and the spacing between the diffusion region of the transistor MP23 of the cell CL1 and the P+ diffusion interconnect 102b of the cell CL2b, are equal to the minimum value SP under the design rules. Therefore, in the cell CL1, it is unnecessary to divide the transistors MP21 and MP23 placed in the N-well NW into parts, and each of such transistors can be configured as one transistor having a large gate width.

Also, a sufficient overlap ovl1 is secured from the right end of the P+ diffusion interconnect 102a to a rightmost contact 103_2a in the cell CL2a, and from the left end of the P+ diffusion interconnect 102b to a leftmost contact 103_3b in the cell CL2b. By this, occurrence of a design rule error can be prevented in the layout verification step S13.

Moreover, the N+ diffusion interconnects 107a, 207, 107b, and 107c placed along the bottom ends of the cells CL2a, CL1, CL2b, and CL2c are connected to one another, and the P+ diffusion interconnects 102b and 102c placed along the top ends of the cells CL2b and CL2c are connected to each other. That is, the regions of the diffusion interconnects and the number of contacts between the diffusion interconnects and the ground interconnects or the power supply interconnects made of metal interconnects are not reduced so largely. Therefore, increase of resistance value in the supply of the ground potential or the power supply potential is minimized.

Also, in the cell CL2b, the spacing between the cell boundary with the cell CL1 and the contact, out of the contacts placed on the P+ diffusion interconnect 102b, closest to this cell boundary is larger than the spacing between this cell boundary and the contact, out of the contacts placed on the N+ diffusion interconnect 107b, closest to the cell boundary. Likewise, in the cell CL2a, the spacing between the cell boundary with the cell CL1 and the contact, out of the contacts placed on the P+ diffusion interconnect 102a, closest to this cell boundary is larger than the spacing between this cell boundary and the contact, out of the contacts placed on the N+ diffusion interconnect 107a, closest to the cell boundary.

When viewed with reference to the position of the diffusion region of the transistor MP23 in the cell width direction, the spacing in the cell width direction between the contact, out of the contacts placed on the P+ diffusion interconnect 102b, closest to the diffusion region of the transistor MP23 in the cell width direction and the diffusion region of the transistor MP23 is larger than the spacing in the cell width direction between the contact, out of the contacts placed on the N+ diffusion interconnect 107b, closest to the diffusion region of the transistor MP23 in the cell width direction and the diffusion region of the transistor MP23. Likewise, when viewed with reference to the position of the diffusion region of the transistor MP21 in the cell width direction, the spacing in the cell width direction between the contact, out of the contacts placed on the P+ diffusion interconnect 102a, closest to the diffusion region of the transistor MP21 in the cell width direction and the diffusion region of the transistor MP21 is larger than the spacing in the cell width direction between the contact, out of the contacts placed on the N+ diffusion interconnect 107a, closest to the diffusion region of the transistor MP21 in the cell width direction and the diffusion region of the transistor MP21.

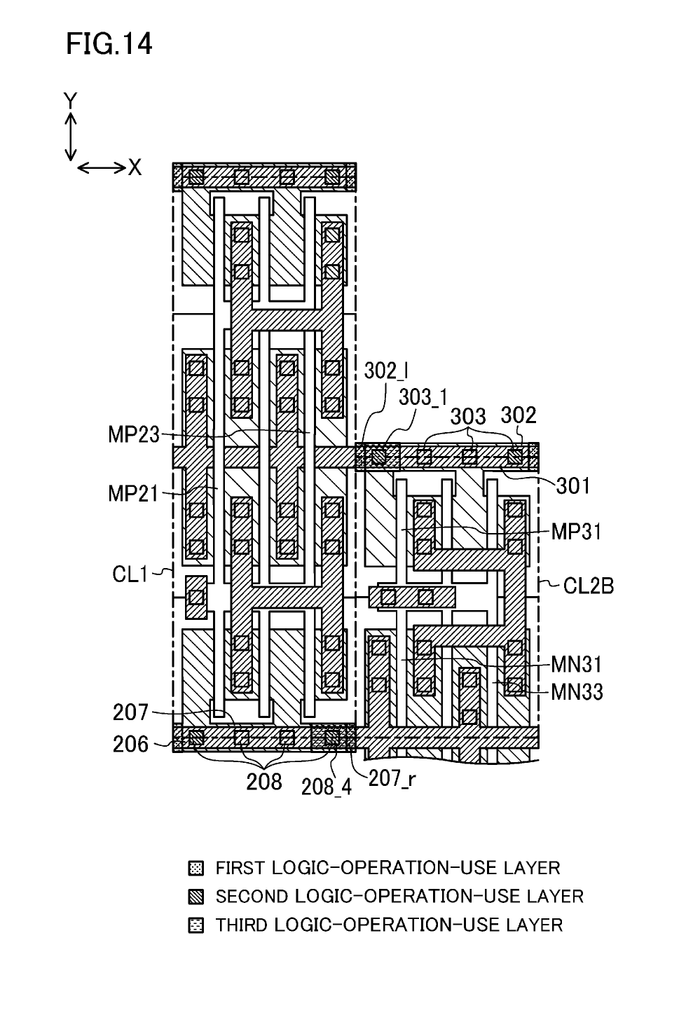

FIG. 14 shows an example of layout design data created in the layout design step S11, in which a double-height cell CL2B where the N-well NW and the P-well PW in the double-height cell CL1 in FIG. 11 are interchanged with each other is placed on the right side of the double-height cell CL1 in the cell width direction. The cell CL2B is placed so that the top end thereof is aligned with the center portion of the cell CL1.

In the layer logic operation step S12, in the cell CL1, a range 207_{—}r of the N+ diffusion interconnect 207 inward from the right end of the cell by a distance of ½ SP and a contact 208_4, out of the contacts on the N+ diffusion interconnect 207, closest to the right end of the cell are deleted. Likewise, in the cell CL2B, a range 302_1 of the P+ diffusion interconnect 302 inward from the left end of the cell by a distance of ½ SP and a contact 303_1, out of the contacts on the P+ diffusion interconnect 302, closest to the left end of the cell are deleted.

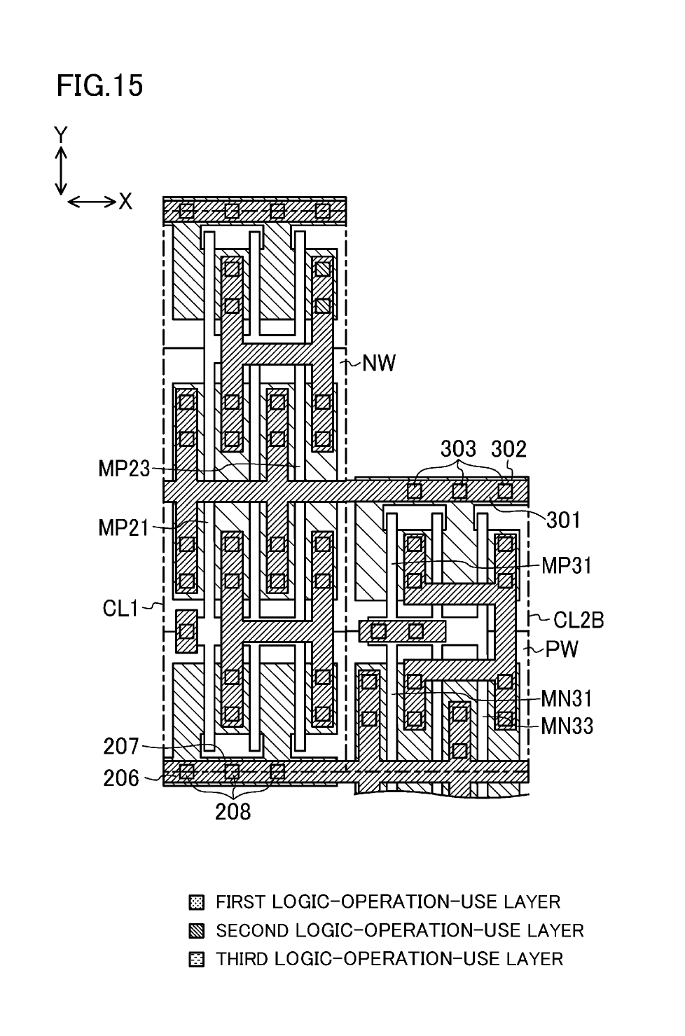

FIG. 15 shows layout design data after execution of the layer logic operation step S12, which corresponds to a layout plan view of the semiconductor integrated circuit device of this embodiment. Note that interconnects between the standard cells formed in the layout design step S11 are omitted in FIG. 15. In FIG. 15, the spacing between the diffusion region of the transistor MP23 of the cell CL1 and the P+ diffusion interconnect 302 of the cell CL2B, and the spacing between the diffusion region of the transistor MN31 of the cell CL2B and the N+ diffusion interconnect 207 of the cell CL1, are equal to the minimum value SP under the design rules. Therefore, it is unnecessary to divide the transistor placed in the N-well NW of the cell CL1, and the transistor placed in the P-well PW of the cell CL2B, into parts, and each of such transistors can be configured as one transistor having a large gate width.

That is, the layout configurations in FIGS. 13 and 15 have similar features to those in the first and second embodiments as the semiconductor integrated circuit device, and thus similar advantages are obtained.

As described above, in this embodiment, in the design data of a cell, the first logic-operation-use layers are provided at the right and left ends of the diffusion interconnects placed along the top and bottom ends of the cell, and the second logic-operation-use layers are provided on the contacts closest to the right and left ends of the diffusion interconnects. Also, in the double-height cell, the third logic-operation-use layers extending right and left from the cell frame are provided in the center portion in the cell height direction. For such layout design data, layer logic operation as follows is performed: i.e., portions of the diffusion interconnects where the first logic-operation-use layers and the third logic-operation-use layers overlap are deleted, and contacts in portions where the second logic-operation-use layers and the third logic-operation-use layers overlap are deleted. By such a design flow, it is unnecessary to divide a transistor placed in the center portion of the double-height cell into parts under the layout rules related to an adjoining cell, and such a transistor can be configured as one transistor having a large gate width.

Note that, while the contacts on the diffusion interconnects are placed on the same grid as the contacts of the transistors in this embodiment, they may be displaced by a half grid spacing, for example. In this case, it is unnecessary to use the second logic-operation-use layers for deleting contacts on the diffusion interconnects, and the contacts can be placed uniformly.

### Fourth Embodiment

The fourth embodiment also follows the design flow in FIG. 9. That is, layout design data is created using design data of a cell having logic-operation-use layers. Thereafter, layer logic operation is performed, which includes deleting portions of the diffusion interconnects where the first logic-operation-use layers and the third logic-operation-use layers overlap and deleting contacts in portions where the second logic-operation-use layers and the third logic-operation-use layers overlap.

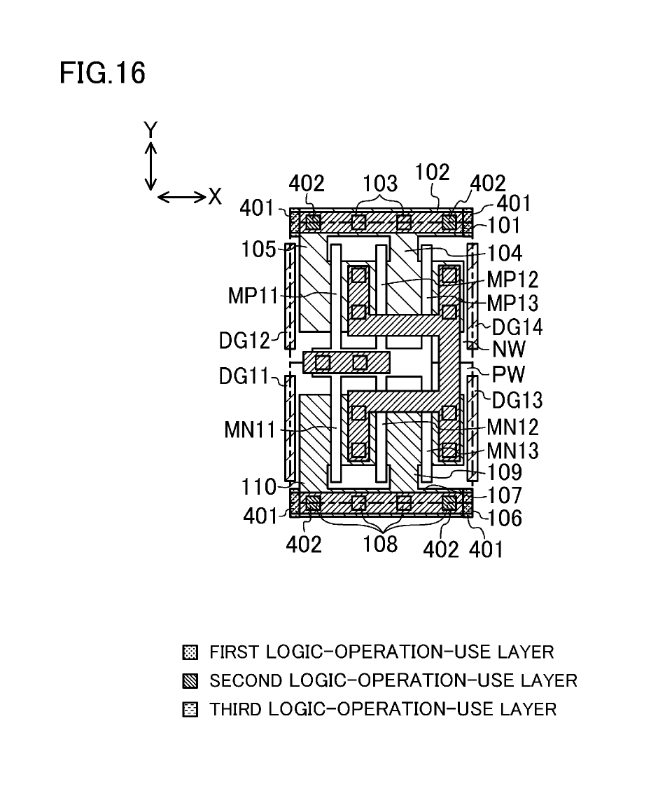

FIG. 16 is a view showing design data of a single-height cell in this embodiment. The configuration in FIG. 16 is roughly similar to that in FIG. 10. The difference is that dummy gates DG11 and DG13 are placed on both ends of the P-well PW and dummy gates DG12 and DG14 are placed on both ends of the N-well NW.

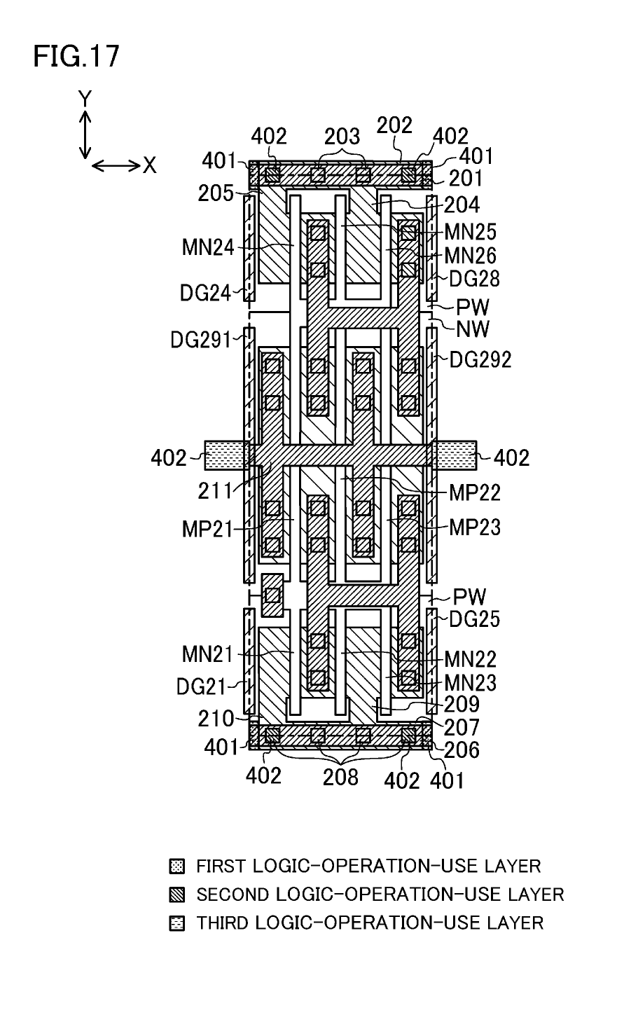

FIG. 17 is a view showing design data of a double-height cell in this embodiment. The configuration in FIG. 17 is roughly similar to that in FIG. 11. The difference is that dummy gates DG291 and DG292 are placed on both ends of the N-well NW, dummy gates DG21 and DG25 are placed on both ends of the lower P-well PW, and dummy gates DG24 and DG28 are placed on both ends of the upper P-well PW. The dummy gates DG291 and DG292 extend over roughly the entire range of the N-well NW so as to stride across the center portion of the cell in the cell height direction. Therefore, the length of the dummy gates DG291 and DG292 in the cell height direction is longer than the gate width of the transistors MP21 and MP23.

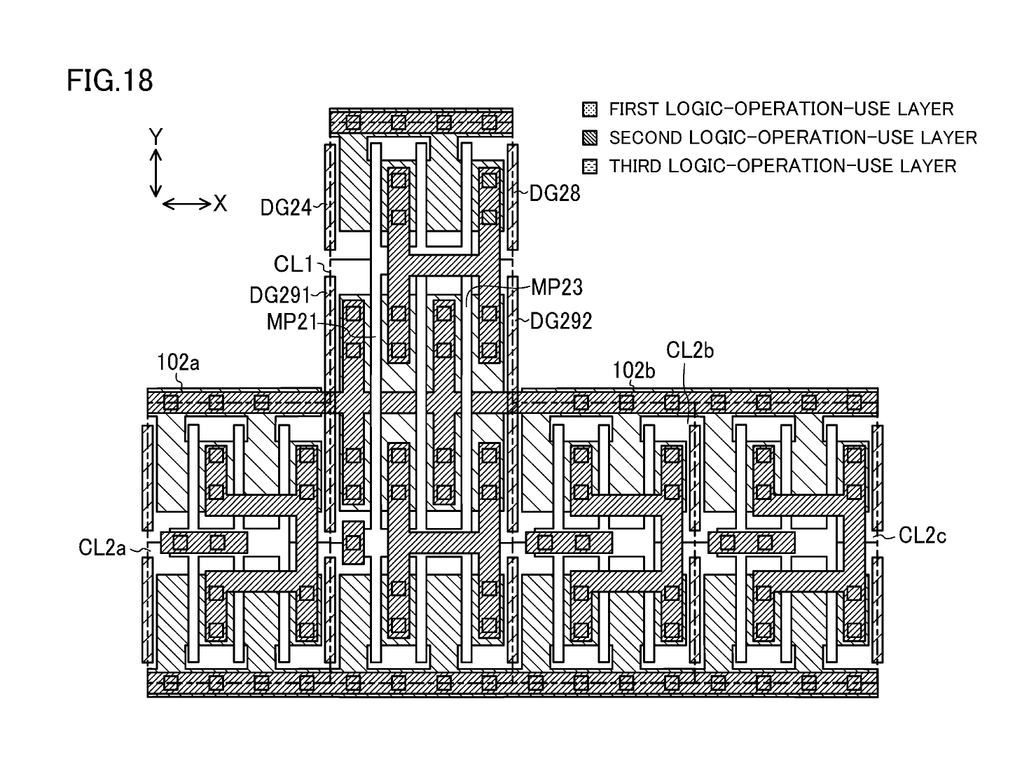

FIG. 18 shows layout design data created and modified in the layout design step S11 and the layer logic operation step S12, which corresponds to a layout plan view of a semiconductor integrated circuit device of this embodiment. In FIG. 18, single-height cells CL2a, CL2b, and CL2c having the configuration shown in FIG. 16 are placed on both sides of a double-height cell CL1 having the configuration shown in FIG. 17 in the cell width direction. The cells CL1, CL2a, CL2b, and CL2c are placed so that the bottom ends of their cell frames are aligned with one another in the cell height direction. Note that interconnects between the standard cells formed in the layout design step S11 are omitted in FIG. 18.

In FIG. 18, as in FIG. 13, by the layer logic operation step S12, the range of the P+ diffusion interconnect 102a of the cell CL2a inward from the right end of the cell by a distance of ½ SP and the range of the P+ diffusion interconnect 102b of the cell CL2b inward from the left end of the cell by a distance of ½ SP are omitted. That is, the spacing SP is secured between the diffusion region of the transistor MP21 of the cell CL1 and the P+ diffusion interconnect 102a of the cell CL2a, and between the diffusion region of the transistor MP23 of the cell CL1 and the P+ diffusion interconnect 102b of the cell CL2b. Accordingly, with the dummy gates DG291 and DG292 not overlapping any diffusion interconnect, formation of an unnecessary transistor is avoided. It is therefore possible to prevent or reduce variations in the shape of the gate electrodes of the transistors of the cell CL1.

As described above, in this embodiment, dummy gates can be placed on both outermost sides of the transistors in the center portion of the double-height cell without formation of an unnecessary transistor. This can prevent or reduce variations in the shape of the gate electrodes of the transistors placed in the center portion of the double-height cell.

In FIG. 18, dummy gates are added to the configuration in FIG. 13 described in the third embodiment. It is however needless to mention that a similar advantage can also be obtained by adding dummy gates to the configurations described in the first and second embodiments, for example, in a similar way. For example, in the layout in FIG. 3 or FIG. 6, a dummy gate may be placed to extend in the cell height direction along the spacing where the diffusion region D_MP23 of the transistor MP23 of the cell CL1 and the P+ diffusion interconnect 102 of the cell CL2 are opposed. That is, in the embodiments described above, no gate interconnect is placed, or only one gate interconnect is placed, between the rectangular transistor diffusion region of the multi-height cell and the opposed diffusion interconnect of its adjoining cell.

While the configuration where an N-well is placed in the center portion of a double-height cell and a diffusion interconnect of another cell is placed to adjoin the N-well has been described as an example in the above embodiments, the disclosure is not limited to this. For example, a configuration where a P-well is placed in the center portion of a double-height cell and a diffusion interconnect of another cell is placed to adjoin the P-well is also applicable like the above embodiments.

In the above embodiments, the configuration where a double-height cell is adjoined by another cell has been described as an example. However, the disclosure is not limited to the double-height cell, but the above embodiments are also applicable as far as having a configuration that a multi-height cell having a cell height N times as large as the reference cell height (N is an integer equal to or more than 2) is adjoined by another cell. That is, the above embodiments are effective as far as the multi-height cell has a large well region and a diffusion interconnect of another cell is placed to adjoin this well region.

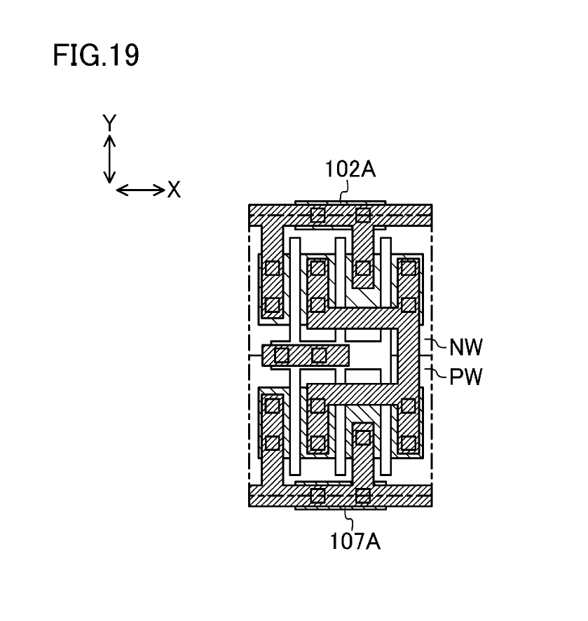

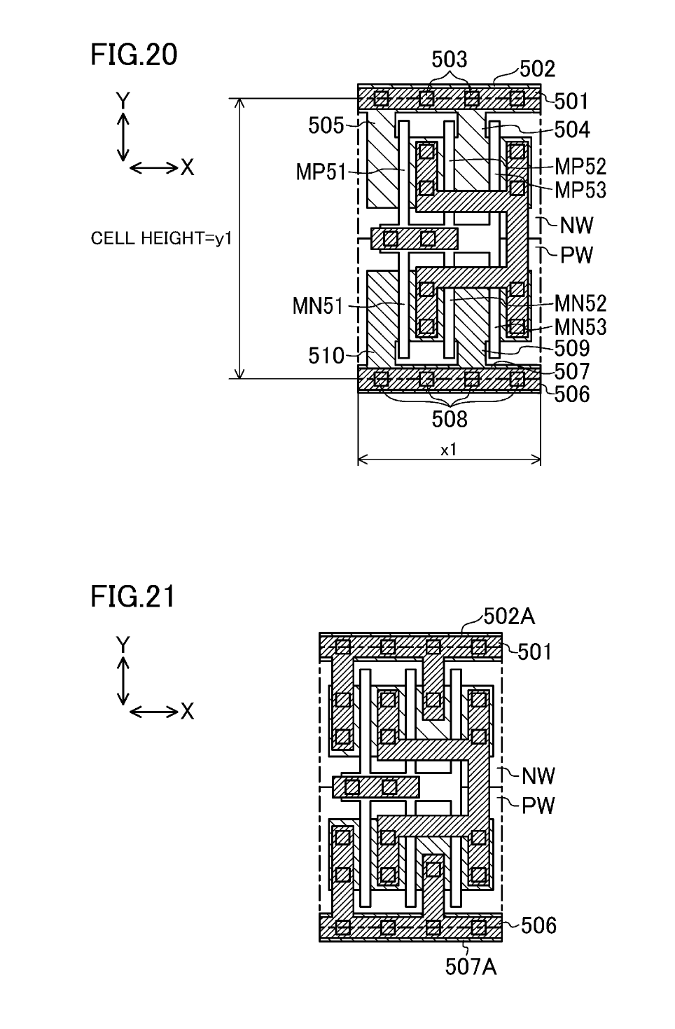

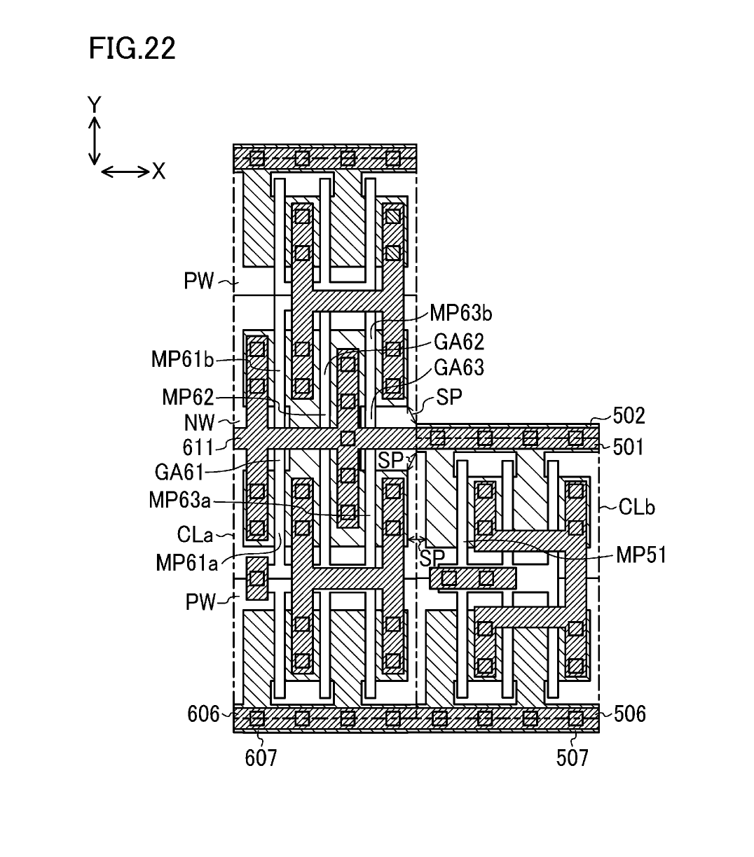

While the configuration where the diffusion interconnects placed along the top and bottom ends of a cell are connected to the source regions of the transistors has been described as an example in the above embodiments, the P/N types of the diffusion interconnects placed along the top and bottom ends of the cell may be inverted, to use the diffusion interconnects to fix the substrate potential, for example. With this configuration, also, a similar advantage can be obtained. For example, FIG. 19 shows an example of a configuration changed from the single-height cell in FIG. 1 so as to use the diffusion interconnects for fixing the substrate potential. In FIG. 19, an N+ diffusion interconnect 102A is used for fixing the potential of the N-well NW, and a P+ diffusion interconnect 107A is used for fixing the potential of the P-well PW.

According to the present disclosure, in the semiconductor integrated circuit device, the drive capability of transistors in a multi-height cell can be improved. Such a device is therefore effective in reducing the area of LSI and improving the performance thereof, for example.

What is claimed is:

1. A semiconductor integrated circuit device where a plurality of cells are placed, the plurality of cells including:
a first cell that is a multi-height cell having a cell height N times as large as a reference cell height (N is an integer equal to or more than 2); and
a second cell placed to adjoin the first cell in a cell width direction,
wherein
the second cell includes
a first metal interconnect placed to extend in the cell width direction along one end in a cell height direction, and
a first diffusion interconnect that is made of an impurity diffusion region formed to extend under the first metal interconnect in the cell width direction and connected to the first metal interconnect via contacts,
the first cell includes
a first transistor diffusion region that is opposed to the first diffusion interconnect in the cell width direction, is formed to stride across, in the cell height direction, a region extended in the cell width direction of the first metal interconnect, and constitutes a transistor, and
the first diffusion interconnect is placed apart from a cell boundary between the first cell and the second cell in the cell width direction.

2. The semiconductor integrated circuit device of claim 1, wherein
the second cell is a single-height cell having the reference cell height and includes a second metal interconnect placed to extend in the cell width direction along the other end in the cell height direction,
the first cell includes a third metal interconnect placed to extend in the cell width direction along one end in the cell height direction, and
the second metal interconnect of the second cell and the third metal interconnect of the first cell are placed to be in line with each other in the cell width direction and connected to each other.

3. The semiconductor integrated circuit device of claim 2, wherein
the second cell further includes a second diffusion interconnect that is made of an impurity diffusion region formed to extend under the second metal interconnect in the cell width direction and connected to the second metal interconnect via contacts, and
the second diffusion interconnect is placed apart from the cell boundary between the first cell and the second cell in the cell width direction.

4. The semiconductor integrated circuit device of claim 3, wherein
the first cell further includes a third diffusion interconnect that is made of an impurity diffusion region formed to extend under the third metal interconnect in the cell width direction and connected to the third metal interconnect via contacts, and
the third diffusion interconnect is placed apart from the cell boundary between the first cell and the second cell in the cell width direction.

5. The semiconductor integrated circuit device of claim 4, wherein
in the first cell, the placement position of the contacts for connecting the third metal interconnect and the third diffusion interconnect is displaced in the cell width direction from the placement position of contacts formed on diffusion regions constituting transistors.

6. The semiconductor integrated circuit device of claim 4, wherein
the spacing between a contact, out of the contacts for connecting the third metal interconnect and the third diffusion interconnect in the first cell, closest to the cell boundary and the cell boundary is equal to the spacing between a contact, out of the contacts for connecting the second metal interconnect and the second diffusion interconnect in the second cell, closest to the cell boundary and the cell boundary.

7. The semiconductor integrated circuit device of claim 2, wherein
the plurality of cells include third and fourth cells placed to adjoin each other in the cell width direction,
the third and fourth cells are placed to adjoin the first and second cells in the cell height direction so as to share the second and third metal interconnects,
the position of a cell boundary between the third and fourth cells in the cell width direction is displaced from the position of the cell boundary between the first and second cells in the cell width direction, and
a second diffusion interconnect that is made of an impurity diffusion region formed to extend under the second and third metal interconnects in the cell width direction and connected to the second and third metal interconnects via contacts is placed continuously across the cell boundary between the first and second cells in the cell width direction.

8. The semiconductor integrated circuit device of claim 2, wherein
the second cell further includes a second diffusion interconnect that is made of an impurity diffusion region formed to extend under the second metal interconnect in the cell width direction and connected to the second metal interconnect via contacts, and
the spacing between a contact, out of the contacts for connecting the first metal interconnect and the first diffusion interconnect in the second cell, closest to the cell boundary and the cell boundary is larger than the spacing between a contact, out of the contacts for connecting the second metal interconnect and the second diffusion interconnect in the second cell, closest to the cell boundary and the cell boundary.

9. The semiconductor integrated circuit device of claim 1, wherein
in the second cell, the placement position of the contacts for connecting the first metal interconnect and the first diffusion interconnect is displaced in the cell width direction from the placement position of contacts formed on diffusion regions constituting transistors.

10. The semiconductor integrated circuit device of claim 1, wherein
the second cell is a multi-height cell having a cell height M times as large as the reference cell height (M is an integer equal to or more than 2),
the first cell further includes
a third metal interconnect placed to extend in the cell width direction along one end in the cell height direction, and
a third diffusion interconnect that is made of an impurity diffusion region formed to extend under the third metal interconnect in the cell width direction and connected to the third metal interconnect via contacts,
the second cell includes
a second transistor diffusion region that is opposed to the third diffusion interconnect in the cell width direction, is formed to stride across, in the cell height direction, a region extended in the cell width direction of the third metal interconnect, and constitutes a transistor, and
the third diffusion interconnect is placed apart from the cell boundary between the first cell and the second cell in the cell width direction.

11. The semiconductor integrated circuit device of claim 1, wherein
a dummy gate is formed to extend in the cell height direction in a spacing where the first transistor diffusion region and the first diffusion interconnect are opposed.

12. A semiconductor integrated circuit device where a plurality of cells are placed, the plurality of cells including:
a first cell that is a multi-height cell having a cell height N times as large as a reference cell height (N is an integer equal to or more than 2); and
a second cell placed to adjoin the first cell in a cell width direction,
wherein
the second cell includes
a first metal interconnect placed to extend in the cell width direction along one end in a cell height direction,
a first diffusion interconnect that is made of an impurity diffusion region formed to extend under the first metal interconnect in the cell width direction and connected to the first metal interconnect via contacts, and
a first diffusion region constituting a transistor,
the first cell includes
a first transistor diffusion region that is opposed to the first diffusion interconnect and the first diffusion region in the cell width direction, is formed to stride across, in the cell height direction, a region extended in the cell width direction of the first metal interconnect, and constitutes a transistor, and
the spacing between the first diffusion interconnect and the first transistor diffusion region is equal to or more than the minimum spacing between the first diffusion region and the first transistor diffusion region.

13. The semiconductor integrated circuit device of claim 12, wherein
the second cell is a single-height cell having the reference cell height and includes a second metal interconnect placed to extend in the cell width direction along the other end in the cell height direction,
the first cell includes a third metal interconnect placed to extend in the cell width direction along one end in the cell height direction, and
the second metal interconnect of the second cell and the third metal interconnect of the first cell are placed to be in line with each other in the cell width direction and connected to each other.

14. The semiconductor integrated circuit device of claim 13, wherein
the second cell further includes a second diffusion interconnect that is made of an impurity diffusion region formed to extend under the second metal interconnect in the cell width direction and connected to the second metal interconnect via contacts, and
the spacing in the cell width direction between a contact, out of the contacts for connecting the first metal interconnect and the first diffusion interconnect in the second cell, closest to the first transistor diffusion region in the cell width direction and the first transistor diffusion region is larger than the spacing in the cell width direction between a contact, out of the contacts for connecting the second metal interconnect and the second diffusion interconnect in the second cell, closest to the first transistor diffusion region in the cell width direction and the first transistor diffusion region.

15. The semiconductor integrated circuit device of claim 12, wherein
in the second cell, the placement position of the contacts for connecting the first metal interconnect and the first diffusion interconnect is displaced in the cell width direction from the placement position of contacts formed on diffusion regions constituting transistors.

16. The semiconductor integrated circuit device of claim 12, wherein
a dummy gate is formed to extend in the cell height direction in a spacing where the first transistor diffusion region and the first diffusion interconnect are opposed.

17. A semiconductor integrated circuit device where a plurality of cells are placed, the plurality of cells including:
a first cell that is a multi-height cell having a cell height N times as large as a reference cell height (N is an integer equal to or more than 2); and
a second cell placed to adjoin the first cell in a cell width direction,
wherein
the second cell includes
a first metal interconnect placed to extend in the cell width direction along one end in a cell height direction, and
a first diffusion interconnect that is made of an impurity diffusion region formed to extend under the first metal interconnect in the cell width direction and connected to the first metal interconnect via contacts,
the first cell includes
a first transistor diffusion region that is opposed to the first diffusion interconnect in the cell width direction, is formed to stride across, in the cell height direction, a region extended in the cell width direction of the first metal interconnect, constitutes a transistor, and is rectangular, and
no gate interconnect is placed, or only one gate interconnect is placed, between the first diffusion interconnect and the first transistor diffusion region.

18. The semiconductor integrated circuit device of claim 17, wherein
the second cell is a single-height cell having the reference cell height and includes a second metal interconnect placed to extend in the cell width direction along the other end in the cell height direction,
the first cell includes a third metal interconnect placed to extend in the cell width direction along one end in the cell height direction, and
the second metal interconnect of the second cell and the third metal interconnect of the first cell are placed to be in line with each other in the cell width direction and connected to each other.

19. The semiconductor integrated circuit device of claim 18, wherein
the second cell further includes a second diffusion interconnect that is made of an impurity diffusion region formed to extend under the second metal interconnect in the cell width direction and connected to the second metal interconnect via contacts, and
the spacing in the cell width direction between a contact, out of the contacts for connecting the first metal interconnect and the first diffusion interconnect in the second cell, closest to the first transistor diffusion region in the cell width direction and the first transistor diffusion region is larger than the spacing in the cell width direction between a contact, out of the contacts for connecting the second metal interconnect and the second diffusion interconnect in the second cell, closest to the first transistor diffusion region in the cell width direction and the first transistor diffusion region.

20. The semiconductor integrated circuit device of claim 17, wherein
in the second cell, the placement position of the contacts for connecting the first metal interconnect and the first diffusion interconnect is displaced in the cell width direction from the placement position of contacts formed on diffusion regions constituting transistors.
